(19) United States
(12) Patent Application Publication
(10) Pub. No.: US 2016/0329011 A1
(43) Pub. Date: Nov. 10, 2016

(54) FLEXIBLE DEVICE

(71) Applicant: BOE TECHNOLOGY GROUP CO., LTD., Beijing (CN)

(72) Inventor: Tao WANG, Beijing (CN)

(21) Appl. No.: 14/906,414

(22) PCT Filed: May 18, 2015
(86) PCT No.: PCT/CN2015/079167

§ 371 Date: Jan. 20, 2016

(30) Foreign Application Priority Data
Jan. 21, 2015 (CN) 201510030749.5

(51) Int. Cl. G09G 3/20; G06F 3/041; G06F 1/16; G05B 15/02; H03K 17/96

(52) U.S. Cl. CPC G09G 3/2092; G05B 15/02; H03K 17/9629; G06F 1/1652; G06F 3/0416; G06F 2203/04102

(57) ABSTRACT

The present invention provides a flexible device, which comprises: a flexible panel, which can be deformed by an external action; an sensing module, which is used for sensing the deformation of the flexible panel and emitting an induced signal; a controller, which is used for receiving the induced signal and emitting a control signal; a drive module, which is used for receiving the control signal and generating a corresponding driving signal; and an execution module, which is used for executing a corresponding action according to the driving signal. Utilizing the flexible characteristic of the flexible panel, the present flexible device is operated by arranging sensors thereon, therefore, the present flexible device has a simple structure.

### FIELD OF THE INVENTION

The present invention relates to the field of flexible technology, and in particular to a flexible device.

### BACKGROUND OF THE INVENTION

A flexible panel is obtained by arranging a pixel circuit on a flexible substrate. Since the flexible substrate of the flexible panel can be bent and folded, the requirements of consumers for wearing the flexible panel or carrying the folded flexible panel and the like can be met.

Apple Inc. disclosed an interactive implementation manner of a flexible display in CN103416043A, where different acoustic wave signals are received by internal components to generate feedback information so as to provide certain tactile feedback to a user.

However, the flexible display described above has a too complicated structure, which makes it inconvenient for simplifying the structure and reducing the weight of the flexible display.

### SUMMARY OF THE INVENTION

An object of the present invention is to provide a flexible device, which is simple in structure, easy to implement and relatively simple in operation method. Since the flexible device has a simple structure, it can meet the requirements of consumers for simplified structure and lightweight thereof.

In order to achieve the above object, the present invention provides a flexible device, which comprises:

a flexible panel, which can be deformed by an external action;

an sensing module, which is used for sensing the deformation of the flexible panel and emitting an induced signal;

a controller, which is used for receiving the induced signal and emitting a control signal;

a drive module, which is used for receiving the control signal and generating a corresponding driving signal; and

an execution module, which is used for executing a corresponding action according to the driving signal.

Preferably, the sensing module comprises sensors, wherein the sensors comprise receiving components and emitting components, the emitting components being used for emitting sensing signals and the receiving components being used for receiving the sensing signals and emitting corresponding induced signals.

Preferably, the receiving components and the emitting components are respectively provided at different positions on the flexible panel.

Preferably, the total number of the receiving components and the emitting components within each of the sensors is four, and the receiving components and the emitting components are respectively disposed at four corners on a same side of the flexible panel.

Preferably, each of the sensors is provided on a front surface or a back surface of the flexible panel.

Preferably, the sensors comprise photosensitive sensors, each of which comprises a light emitting component and a plurality of light receiving components, wherein light signals emitted by the light emitting component are received by different light receiving components according to different deformations of the flexible panel, so that different induced signals are emitted.

Preferably, the sensors comprise touch switches, each of which comprises an active touch element and a plurality of touch sensing elements, wherein touches of the active touch element are received by different touch sensing elements according to different deformations of the flexible panel, so that different induced signals are emitted.

Preferably, the sensors emit different induced signals according to different numbers of the contacts between the touch sensing elements and the active touch element within a preset time period.

Preferably, the flexible device further comprises a strain sensor, which is used for detecting whether the flexible panel undergoes a flexible deformation, and for sending a start signal to the controller when the flexible panel undergoes a flexible deformation so that the controller activates the sensors.

Preferably, the strain sensor comprises a strain sheet and a signal generation element, wherein the strain sheet is attached to the back surface of the flexible panel to detect whether the flexible panel undergoes a deformation; and when the strain sheet detects that the flexible panel undergoes a deformation, the signal generation element generates the start signal and sends the same to the controller.

Preferably, the drive module comprises one or more of an audio drive module, a wireless network drive module, a camera drive module, a communication drive module, a power source drive module and a display drive module.

Preferably, the execution module comprises one or more of an audio component, a wireless network component, a camera component, a communication component, a power source component and a display component.

Utilizing the flexible characteristic of the flexible panel, the flexible device provided by the present invention is operated by arranging sensors thereon, therefore, the flexible device provided by the present invention has a simple structure and is relatively easy to operate. Due to its simple structure, the flexible device can meet the requirements of consumers for reducing the weight and size of the flexible device, so that it is more convenient to be carried.

### BRIEF DESCRIPTION OF THE DRAWINGS

Drawings are provided for further understanding of the present invention and constitute a part of the specification to illustrate the present invention together with embodiments in the following, instead of setting a limitation to the present invention. In the drawings:

FIG. 1 is a schematic block diagram of a flexible device provided by the present invention;

FIG. 2 is a schematic diagram of modules of a preferable embodiment of a flexible device provided by the present invention;

FIG. 3 is a schematic diagram of a front view of a flexible device provided by the present invention;

FIG. 4 is a schematic diagram of a side view of the flexible device as shown in FIG. 3;

FIG. 5 shows an interaction relationship between emitting components and receiving components of sensors when the flexible device as shown in FIG. 4 is bent; and

FIG. 6 is a rear view of the flexible device as shown in FIG. 4.

### DESCRIPTION OF REFERENCE SIGNS

| | |
|---|---|
| A: sensing module | B: drive module |
| C: execution module | |
| 100: flexible panel | 101: front surface of flexible panel |
| 102: back surface of flexible panel | 201, 203: emitting component |
| 110: display component | |

202a, 202b, 202c, 204a, 204b, 204c: receiving component

| | |
|---|---|
| 300: controller | 410: wireless network drive module |
| 420: camera drive module | 430: audio drive module |
| 440: display drive module | 450: communication drive module |
| 460: power source drive module | 500: audio component |
| 600: wireless network component | 700: camera |
| 800: communication component | 900: power source component |

### DESCRIPTION OF THE PREFERRED EMBODIMENT

In the following, embodiments of the present invention are described in details with reference to the drawings. It should be understood that the embodiments described herein are only used for explaining and interpreting the present invention, instead of setting a limit to the present invention.

The present invention provides a flexible device, which, as shown in FIG. 1, includes:

a flexible panel 100, which can be deformed by an external action;

a sensing module A, which is used for sensing the deformation of the flexible panel 100 and emitting an induced signal;

a controller 300, which is used for receiving the induced signal and emitting a control signal;

a drive module B, which is used for receiving the control signal and generating a corresponding driving signal; and

an execution module C, which is used for executing a corresponding action according to the driving signal.

The sensing module A, the controller 300, the drive module B and the execution module C are provided on the flexible panel 100. The sensing module A is electrically connected with the controller 300; the controller 300 is electrically connected with the drive module B; and the drive module B is electrically connected with the execution module C. When a user wants to perform a desired operation on the flexible device, he/she applies a corresponding external action to the flexible panel 100 at first so that the flexible panel 100 deforms. After the flexible panel 100 deforms, the sensing module A senses the deformation and generates a corresponding induced signal according to the shape of the deformed panel. The sensing module A sends the induced signal generated thereby to the controller 300, which, upon reception of the induced signal, determines a control signal corresponding to the induced signal, then generates the control signal and sends it to the drive module B corresponding to the control signal. The drive module B generates a corresponding driving signal after receiving the control signal and sends the driving signal to the corresponding execution module C, which may perform a corresponding action according to the received driving signal.

From the description above, it is known that in the flexible device provided by the present invention, operations to the flexible device may be implemented by allowing the flexible panel 100 to deform, without requiring complicated input. Furthermore, the deformation of the flexible panel 100 may be sensed just by providing the sensing module A on the flexible panel 100 and without requiring further complicated structures, therefore, the structure of the flexible device is simplified to facilitate a reduction in weight and size of the flexible display device. In the present invention, the drive module B may be a circuit board integrated with various driving programs. To meet the requirement of reducing the size of the flexible device, a plurality of drive modules B are preferably integrated on the same circuit board.

In the present invention, there is no limit set to the specific structure of the sensing module A. For example, the sensing module A may include sensors, wherein the sensors include receiving components and emitting components, the emitting components being used for emitting sensing signals, and the receiving components being used for receiving the sensing signals and emitting corresponding induced signals,

It is easy to understand that the receiving components are connected with the controller 300, When the flexible panel 100 deforms, the emitting components emit sensing signals and the receiving components receive the sensing signals and generate corresponding induced signals according to the sensing signals.

As a preferable embodiment of the present invention, the receiving components and the emitting components may be provided at different positions on the flexible panel 100. Therefore, the flexible panel 100 may be deformed just by allowing the emitting components to move towards the receiving components, which can be considered to be “the sensing module A senses the deformation of the flexible panel 100”.

In the present invention, different operations can be performed by allowing the flexible panel 100 to deform into different shapes. The more the types of the induced signals generated by the sensing module A are, the more the numbers of the operations to be possibly performed are. Each deformation of the flexible panel 100 corresponds to one type of induced signal, and each type of induced signal corresponds to one operation. In other words, different deformations of the flexible panel 100 correspond to different operations.

To implement that different induced signals are generated in response to different deformations of the flexible panel 100, the flexible device may preferably include a plurality of sensors. In the present invention, there is no specific limit set to the number of the receiving components and emitting components in each sensor. For example, the total number of the emitting components and receiving components included in each of the sensors is four, and the emitting components and the receiving components are respectively disposed at the four corner positions on the same side of the flexible panel 100.

That “the total number of the emitting components and receiving components included in each of the sensors is four” involves the following three cases: (1) three emitting components and one receiving component; (2) one emitting component and three receiving components; and (3) two emitting components and two receiving components. The emitting component(s) and the receiving component(s) are respectively disposed at the four corner positions on the same side of the flexible panel 100 so that the movement of any one of the emitting component towards any one of the receiving component may result in flexible deformation of the flexible panel, resulting that the receiving component(s) receive(s) the sensing signals emitted by the emitting component(s) to generate induced signals.

In the present invention, there is no limit to the specific position of the sensors. For example, the sensors may be disposed on the front surface 101 of the flexible panel, or on the back surface 102 of the flexible panel. Certainly, to increase the number of types of the induced signals, the sensors are further preferably disposed on the front surface 101 and back surface 102 of the flexible panel.

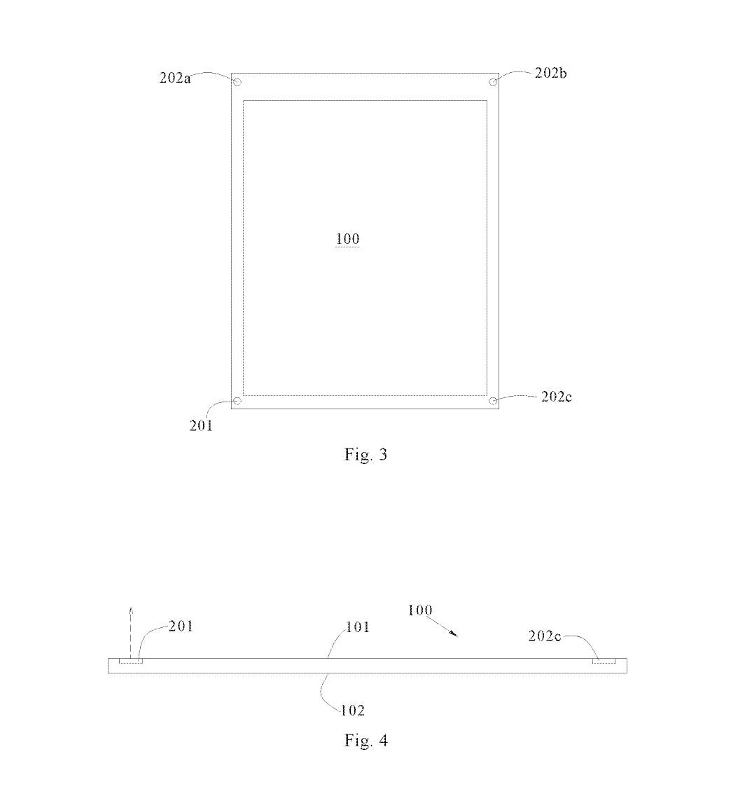

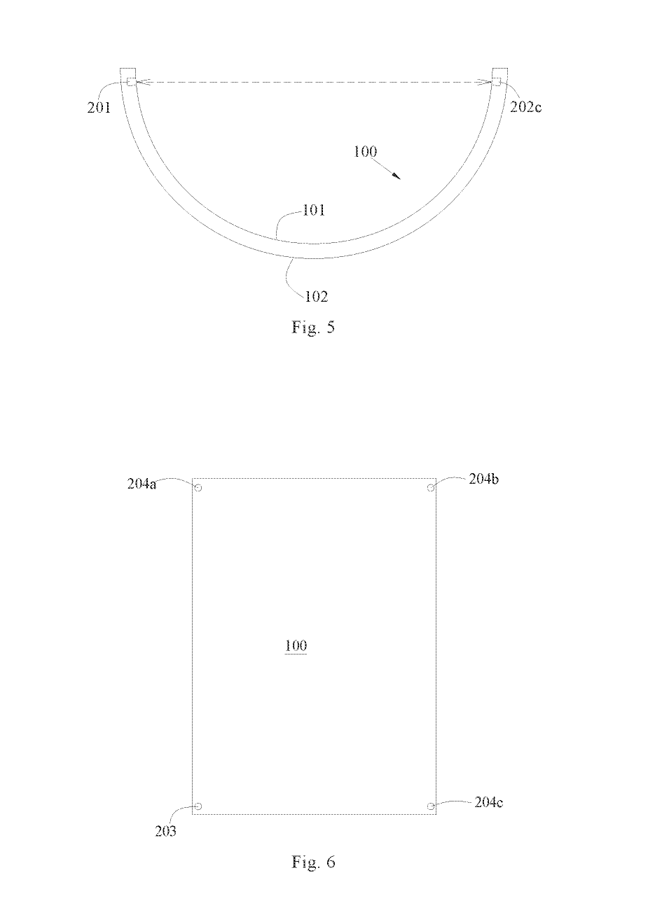

In the embodiment as shown in FIG. 3, the sensor provided on the front surface 101 of the flexible panel includes one emitting component 201 and three receiving components 202a, 202b and 202c. As shown in FIG. 4, when the flexible panel 100 does not deform, the sensing signal (as shown by the dotted arrow) emitted by the emitting component 201 does not reach any one of the receiving components. As shown in FIG. 5, when the flexible panel 100 undergoes a deformation allowing the emitting component 201 to move towards the receiving component 202c, the sensing signal emitted by the emitting component 201 is received by the receiving component 202c. The receiving component 202c generates an induced signal after receiving the sensing signal, wherein the induced signal includes the physical address of the receiving component 202c; and the receiving component 202c sends the induced signal generated thereby to the controller 300.

Certainly, the working principle in the event that the emitting component 201 moves towards other receiving components is also similar that as described above in the event that the emitting component 201 moves towards the receiving component 202c, and the description is not repeated here anymore.

Alternatively/Simultaneously, the sensors may be disposed on the back surface 102 of the flexible panel. As shown in FIG. 6, four corner positions of the back surface 102 of the flexible panel are respectively provided with the emitting component 203 and the receiving components 204a, 204b and 204c.

In the present invention, there is no special limit set to the specific structure of the sensors. For example, the sensors may be photosensitive sensors. Specifically, each of the photosensitive sensors includes a light emitting component and a plurality of light receiving components. Each of the light receiving components is connected with the controller 300 so that the induced signals generated respectively can be sent to the controller 300. It is easy to understand that the physical address of each of the light receiving component is different; the induced signal generated by each of the light receiving components carries a physical address of itself; the controller 300 may determine the receiving component sending the induced signal according to the physical address in the received induced signal, and determine the specific control signal to be generated accordingly.

It is easy to understand that the light emitting component described here is an example of the emitting component described above, and the light receiving component described here is an example of the receiving component described above.

The light emitting component and the plurality of light receiving components are respectively disposed at different positions of the flexible panel 100 so that different light receiving components can receive the light sensing signal emitted by the light emitting component when the flexible panel 100 undergoes different deformations.

As another embodiment of the present invention, the sensors may include touch switches. Specifically, each of the touch switches includes an active touch element and a plurality of touch sensing elements. Touches on the active touch element are received by different touch sensing elements according to different deformations of the flexible panel 100 so that different induced signals are generated to drive different drive modules B. The touch sensing elements, connected with the controller 300, may generate induced signals and send the same to the controller 300 when being collided by the active touch element.

Similar to the photosensitive sensor, the active touch element and the plurality of touch sensing elements are respectively disposed at different positions on the flexible panel 100 (for example, four corner position of the front surface 101 and/or back surface 102 of the flexible panel 100). Each of the touch sensing elements has a unique physical address, and the induced signal emitted by each of the touch sensing elements includes the physical address of itself. After receiving the induced signal, the controller 300 firstly analyzes the physical address of the induced signal so as to determine which touch sensing element sends the induced signal and which control signal corresponds to the induced signal.

It is easy to understand that the touch sensing component is an example of the receiving component described above, and the active touch component is an example of the emitting component described above.

To increase the number of the types of the operations realized due to the deformation of the flexible panel 100, the touch sensing elements preferably emit different induced signals to the controller 300 according to different numbers of the contacts between the active touch element and the touch sensing element within a preset time period.

The preset time period may, for example, range between 1 s and 3 s. The number of the types of the induced signals is further increased by generating different induced signals according to different numbers of the contacts between the touch sensing elements and the active touch element, therefore the number of the types of the operations to be possibly performed based on the deformation of the flexible panel 100 is further increased.

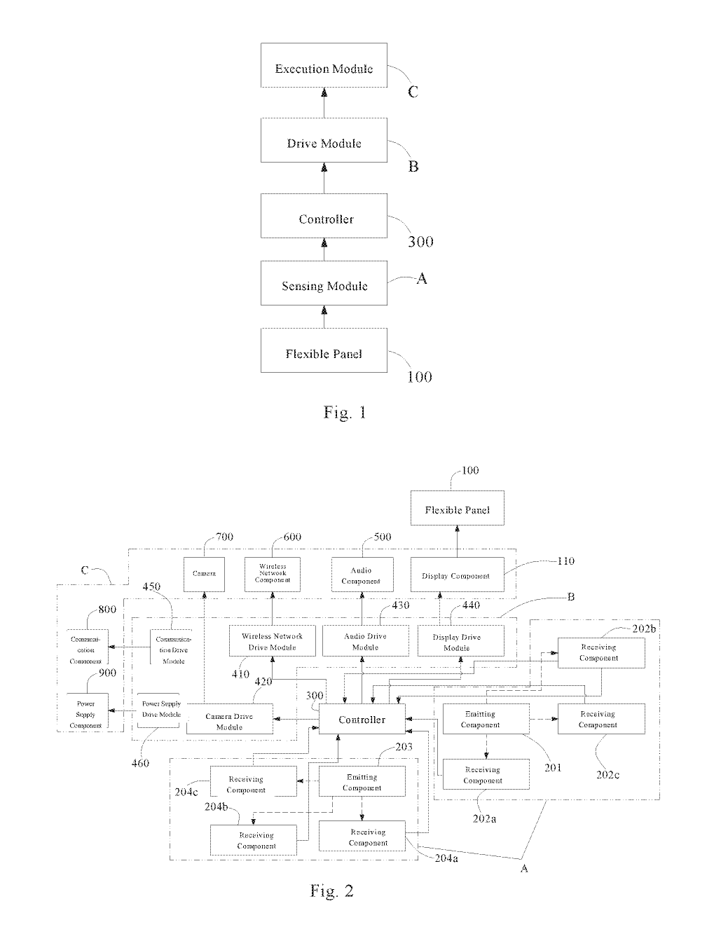

In the present invention, there is no limit set to the specific type of the drive module B. For example, as shown in FIG. 2, the drive module B may include one or more of an audio drive module 430, a wireless network drive module 410, a camera drive module 420, a communication drive module 450, a power source drive module 46 and a display drive module 440.

Correspondingly, as shown in FIG. 2, the execution module C includes one or more of an audio component 500, a wireless network component 600, a camera component (such as a camera 700) a communication component 800, a power source component 900 and a display component 110.

The audio drive module 430 is connected with the audio component 500 and used for driving the audio component 500. The controller 300 is connected with the audio drive module 430, and a first deformation form of the flexible panel 100 may correspond to an operation to the audio component 500, When the flexible panel 100 undergoes the first deformation, the sensors may generate an induced signal corresponding to the driving of the audio component 500 and send the induced signal to the controller 300, the controller 300 sends a control signal to the audio drive module 430 after receiving the induced signal; and the audio drive module 430 generates a driving signal for driving the audio component 500 after receiving the control signal.

The wireless network drive module 410 is connected with the wireless network component 600 and used for driving the wireless network component 600. The controller 300 is connected with the wireless network drive module 410, and a second deformation form of the flexible panel 100 may correspond to an operation to the wireless network component 600. When the flexible panel 100 undergoes the second deformation, the sensors may generate an induced signal corresponding to the driving of the wireless network component 600 and send the induced signal to the controller 300; the controller 300 sends a control signal to the wireless network drive module 410 after receiving the induced signal; and the wireless network drive module 410 generates a driving signal for driving the wireless network component 600 after receiving the control signal.

The camera drive module 420 is connected with the camera 700 and used for driving the camera 700. The controller 300 is connected with the camera drive module 420, and a third deformation form of the flexible panel 100 may correspond to an operation to the camera 700. When the flexible panel 100 undergoes the third deformation, the sensors may generate an induced signal corresponding to the driving of the camera 700 and send the induced signal to the controller 300; the controller 300 sends a control signal to the camera drive module 420 after receiving the induced signal; and the camera drive module 420 generates a driving signal for driving the camera 700 after receiving the control signal.

The communication drive module 450 is connected with the communication component 800 and used for driving the communication component 800. The controller 300 is connected with the communication drive module 450 (not shown in FIG. 2), and a fourth deformation form of the flexible panel 100 may correspond to an operation to the communication component 800. When the flexible panel 100 undergoes the fourth deformation, the sensors may generate an induced signal corresponding to driving the communication component 800 and send the induced signal to the controller 300; the controller 300 sends a control signal to the communication drive module 450 after receiving the induced signal, and the communication drive module 450 generates a driving signal for driving the communication component 800 after receiving the control signal.

The power source drive module 460 is connected with the power source component 900 and used for driving the power source component 900. The controller 300 is connected with the power source drive module 460 (not shown in FIG. 2), and a fifth deformation form of the flexible panel 100 may correspond to an operation to the power source component 900. When the flexible panel 100 undergoes the fifth deformation, the sensors may generate an induced signal corresponding to the driving of the power source component 900 and send the induced signal to the controller 300; the controller 300 sends a control signal to the power source drive module 460 after receiving the induced signal; and the power source drive module 460 generates a driving signal for driving the power source component 900 after receiving the control signal.

The display drive module 440 is connected with the display component 110 and used for driving the display component 110. The controller 300 is connected with the display drive module 440, and a sixth deformation form of the flexible panel 100 may correspond to an operation to the display component 110. When the flexible panel 100 undergoes the sixth deformation, the sensors may generate an induced signal corresponding to driving the display component 110 and send the induced signal to the controller 300; the controller 300 sends a control signal to the display drive module 440 after receiving the induced signals; and the display drive module 440 generates a driving signal for driving the display component 110 after receiving the control signal.

As shown in FIG. 3, the sensors include a sensor disposed on the front surface 101 of the flexible panel 100; and the sensor includes an emitting component 201 for emitting the sensing signals and receiving components 202a, 202b and 202c for receiving the sensing signals. When the flexible panel 100 is a flexible display panel, the front surface 101 of the flexible panel is a display surface of the flexible panel 100, wherein the display surface includes a display region for displaying and a non-display region surrounding the display region. Preferably, the emitting component 201 and the three receiving components 202a, 202b and 202c are disposed at the non-display region so that the normal display of the flexible panel 100 may not be influenced. As shown in FIG. 3, the emitting component 201 and the three receiving components 202a, 202b and 202c are respectively disposed at the four corner positions of the front surface 101 of the flexible panel.

As shown in FIG. 6, the sensors may also include a sensor provided on the back surface 102 of the flexible panel 100, which includes an emitting component 203 for emitting the sensing signals and receiving components 204a, 204b and 204c for receiving the sensing signals.

It is easy to understand that all of the receiving components 202a, 202b and 202c and the receiving components 204a, 204b and 204c are used for generating the induced signals when receiving the sensing signals.

It should be noted that the physical addresses of the three receiving components 202a, 202b and 202c are different, therefore, the physical addresses included in the induced signals generated are different; and the physical addresses of the three receiving components 204a, 204b and 204c are different, therefore, the physical addresses included in the induced signals generated are also different. Moreover, the physical addresses in the induced signals emitted by the six receiving components (i.e. the receiving components 202a, 202b and 202c and the receiving components 204a, 204b and 204c ) are different.

The flexible panel 100 may be in different preset bending shapes so that different receiving components move towards the emitting component 201 or 203.According to the different bending shapes of the flexible panel 100, different receiving components may generate the induced signals having specific physical addresses.

As shown in FIG. 4, when the flexible panel 100 does not undergo a preset bending deformation, the receiving component 202c does not receive the induced signal (as shown by the dotted line) emitted by the emitting component 201. Therefore, the receiving component 202c will not generate the induced signal either, and further, any one of the other receiving components will not generate the induced signal.

As shown in FIG. 5, when the flexible panel 100 undergoes a preset bending deformation, the sensing signal emitted by the emitting component 201 reaches the receiving component 202c, therefore, the receiving component 202c will generate an induced signal which includes a physical address of the receiving component 202c.

For the sensor provided on the front surface 101 of the flexible panel 100, said different preset bending shapes of the flexible panel 100 may include the following three forms: firstly, a deformation allowing the sensing signal emitted by the emitting component 201 to reach the receiving component 202a; secondly, a deformation allowing the sensing signal emitted by the emitting component 201 to reach the receiving component 202b; and thirdly, a deformation allowing the sensing signal emitted by the emitting component 201 to reach the receiving component 202b (as shown in FIG. 5).

It should be noted that FIG. 4 and FIG. 5 are only used to illustrate the working principle of the sensor provided on the front surface 101 of the flexible panel 100 and do not show the sensor provided on the back surface 102 of the flexible panel 100, which does not mean that no sensor is provided on the back surface 102 of the flexible panel 100.

The bending shape of the flexible panel 100 corresponding to the moment when the receiving components receive the sensing signal emitted by the emitting component 201 is different from the bending shape of the flexible panel 100 corresponding to the moment when the receiving components receive the sensing signal emitted by the emitting component 203, therefore, the operation corresponding to the moment when the sensor provided on the front surface 101 of the flexible panel 100 generates the sensing signal is different from the operation corresponding to the moment when the sensor provided on the back surface 102 of the flexible panel 100 generates the sensing signal.

Similar to the sensor provided on the front surface 101 of the flexible panel 100, for the sensor provided on the back surface 102 of the flexible panel 100; said different preset bending shapes of the flexible panel 100 may include the following three forms: firstly, a deformation allowing the sensing signal emitted by the emitting component 203 to reach the receiving component 204a; secondly, a deformation allowing the sensing signal emitted by the emitting component 203 to reach the receiving component 204b; and thirdly, a deformation allowing the sensing signal emitted by the emitting component 203 to reach the receiving component 204c.

In a preferable embodiment of the present invention, the sensor provided on the front surface 101 of the flexible panel includes an emitting component 201 and three receiving components 202a, 202b and 202c; and the sensor provided on the back surface 102 of the flexible panel includes an emitting component 203 and three receiving components 204a, 204b and 204c. When the flexible device includes the six execution modules C as shown in FIG. 2, the flexible panel 100 may be bent into the following six shapes:

a bending shape corresponding to the adjustment of the audio component 500, where a first receiving component of the three receiving components in the sensor provided on the front surface 101 of the flexible panel is moved towards the emitting component of the sensor provided on the front surface 101 of the flexible panel so that the first receiving component can receive the sensing signal emitted by the emitting component;

a bending shape corresponding to the adjustment of the wireless network component 600, where a second receiving component of the three receiving components in the sensor provided on the front surface 101 of the flexible panel is moved towards the emitting component of the sensor provided on the front surface 101 of the flexible panel so that the second receiving component can receive the sensing signal emitted by the emitting component;

a bending shape corresponding to the adjustment of the camera 700, where a third receiving component of the three receiving components in the sensor provided on the front surface 101 of the flexible panel is moved towards the emitting component of the sensor provided on the front surface 101 of the flexible panel so that the third receiving component can receive the sensing signal emitted by the emitting component;

a bending shape corresponding to the adjustment of the communication component 800, where a first receiving component of the three receiving components in the sensor provided on the back surface 102 of the flexible panel is moved towards the emitting component of the sensor provided on the back surface 102 of the flexible panel so that the first receiving component can receive the sensing signal emitted by the emitting component;

a bending shape corresponding to the adjustment of the power source component 900, where a second receiving component of the three receiving components in the sensor provided on the back surface 102 of the flexible panel is moved towards the emitting component of the sensor provided on the back surface 102 of the flexible panel so that the second receiving component can receive the sensing signal emitted by the emitting component; and

a bending shape corresponding to the adjustment of the display component 110, where a third receiving component of the three receiving components in the sensor provided on the back surface 102 of the flexible panel is moved towards the emitting component of the sensor provided on the back surface 102 of the flexible panel so that the third receiving component can receive the sensing signal emitted by the emitting component.

It is easy to understand that the terms “first”, “second” and “third” as used above are only used to distinguish the different receiving components located on the same side.

Correspondingly, the operation to the audio component 500 includes increasing and/or decreasing volume;

the operation to the wireless network component 600 includes turning on or turning off the wireless network component 600;

the operation to the camera 700 includes turning on or turning off the camera 700;

the operation to the communication component 800 includes getting through and/or hanging up a phone;

the operation to the power source component 900 includes startup and/or shutdown; and

the operation to the display component 110 includes locking and/or unlocking a screen.

In the following, a preferable embodiment of the flexible device provided by the present invention is described with reference to FIGS. 2 through 6.

A sensing module A includes a sensor provided on a front surface 101 of a flexible panel 100, a sensor provided on a back surface 102 of the flexible panel 100, a controller 300, a plurality of drive modules B and a plurality of execution modules C. The sensor provided on the front surface 101 of the flexible panel 100 includes an emitting component 201 and receiving components 202a, 202b and 202c; the sensor provided on the back surface 102 of the flexible panel 100 includes an emitting component 203 and receiving components 204a, 204b and 204c; the plurality of drive modules B are respectively a wireless network drive module 410, a camera drive module 420, an audio drive module 430, a display drive module 440,a communication drive module 450 and a power source drive module 460; and the plurality of execution modules C are respectively a display component 110 connected with the display drive module 440, an audio component 500 connected with the audio drive module 430, a wireless network component 600 connected with the wireless network drive module 410, a camera component (a camera 700) connected with the camera drive module 420,a communication component 800 connected with the communication drive module 450 and a power source component 900 connected with the power source drive module 460. Certainly, the flexible device may also include other execution modules C and drive modules B allowing the flexible device to realize other functions. It should be understood that the arrangement manner of the sensor on the front surface 101 of the flexible panel 100 is as shown in FIG. 3, and the arrangement manner of the sensor on the back surface 102 of the flexible panel 100 is as shown in FIG. 6.

Both groups of the sensors (i.e. the sensing module A) as shown in FIG. 2 may be photosensitive sensors. Correspondingly, the preset bending shapes of the flexible panel 201 include the following six forms: firstly, a deformation allowing the sensing signal emitted by the emitting component 201 to reach the receiving component 202a; secondly, a deformation allowing the sensing signal emitted by the emitting component 201 to reach the receiving component 202b; thirdly, a deformation allowing the sensing signal emitted by the emitting component 201 to reach the receiving component 202c, fourthly, a deformation allowing the sensing signal emitted by the emitting component 203 to reach the receiving component 204a; fifthly, a deformation allowing the sensing signal emitted by the emitting component 203 to reach the receiving component 204b; and sixthly, deformation allowing the sensing signal emitted by the emitting component 203 to reach the receiving component 204c.

The receiving components 202a, 202b and 202c may generate three types of induced signals having different physical addresses according to the first to the third preset bending shapes; the receiving components 204a, 204b and 204c may generate three types of induced signals having different physical addresses according to the fourth to the sixth preset bending shapes. Therefore, the sensors generate six types of different induced signals in total. Correspondingly, the controller 300 controls the six drive modules B to generate six types of different control signals according to the six types of induced signals having different physical addresses, so that the six drive modules B control the corresponding execution modules C to act respectively.

In the present preferable embodiment, it can be set as follows: the first preset bending shape corresponds to the adjustment of the communication component 800; the second preset bending shape to the adjustment of the audio component 500; the third preset bending shape to the adjustment of the display component 110; the fourth preset bending shape to the adjustment of the camera 700; the fifth preset bending shape to the adjustment of the power source component 900; and the sixth preset bending shape to the adjustment of the wireless network component 600.

When the flexible panel 100 undergoes the first preset bending shape, the receiving component 202a generates an induced signal having the physical address of the receiving component 202a and sends the same to the controller 300; the controller 300 sends a first control signal to the communication drive module 450 after receiving the induced signal having the physical address of the receiving component 202a; and the communication drive module 450 operates the communication component 800 after receiving the first control signal. The operations to the communication component 800 may include getting through and/or hanging up a phone. When there is a coming call, the flexible panel 100 is bent into the first preset bending shape to control the communication component 800 for getting through the phone; and during the call, the flexible panel 100 is bent into the first preset bending shape to control the communication component 800 to hang up the phone. The operation of getting through the phone or hanging up the phone by bending the flexible panel 100 may effectively prevent misoperation caused by sliding on the flexible panel 100 and touching the flexible panel 100.

When the flexible panel 100 undergoes the second preset bending shape, the receiving component 202b generates an induced signal having the physical address of the receiving component 202b and sends the same to the controller 300; the controller 300 sends a second control signal to the audio drive module 430 after receiving the induced signal having the physical address of the receiving component 202b; and the audio drive module 430 operates the audio component 500 after receiving the second control signal. The operations to the audio component 500 may include increasing and/or decreasing volume thereof. For example, the volume can be increased by making the flexible panel bend into the second preset bending shape once within a preset time period (for example, within 2 s); and the volume can be decreased by making the flexible panel bend into the second preset bending shapes twice within the preset time period.

When the flexible panel 100 undergoes the third preset bending shape, the receiving component 202c generates a signal having the physical address of the receiving component 202c and sends the same to the controller 300; the controller 300 sends a third control signal to the display drive module 440 after receiving the induced signal having the physical address of the receiving component 202c; and the display drive module 440 operates the display component 110 after receiving the third control signal. The operations to the display component 110 may include locking and/or unlocking a screen. When the flexible panel 100 is bent into the third preset bending shape, the screen of the display component 110 can be locked or unlocked.

When the flexible panel 100 undergoes the fourth preset bending shape, the receiving component 204a generates an induced signal having the physical address of the receiving component 204a and sends the same to the controller 300; the controller 300 sends a fourth control signal to the camera drive module 420 after receiving the induced signal having the physical address of the receiving component 204a; and the camera drive module 420 operates the camera 700 after receiving the fourth control signal. The operations to the camera 700 may include turning on or turning off the camera 700.

When the flexible panel 100 undergoes the fifth preset bending shape, the receiving component 204b generates an induced signal having the physical address of the receiving component 204b and sends the same to the controller 300; the controller 300 sends a fifth control signal to the power source drive module 460 after receiving the induced signal having the physical address of the receiving component 204b; and the power source drive module 460 operates the power source component 900 after receiving the fifth control signal. The operations to the power source component 900 may include disconnecting or connecting the power source component 900 to realize startup or shutdown of the flexible panel.

When the flexible panel 100 undergoes the sixth preset bending shape, the receiving component 204c generates an induced signal having the physical address of the receiving component 204c and sends the same to the controller 300; the controller 300 sends a sixth control signal to the wireless network drive module 410 after receiving the induced signal having the physical address of the receiving component 204c; and the wireless network drive module 410 operates the wireless network component 600 after receiving the sixth control signal. The operations to the wireless network component 600 may include startup and/or shutdown of the wireless network component 600; the startup of the wireless network component 600 includes enabling a WIFI function or enabling a Bluetooth function; and the shutdown of the wireless network component 600 includes disabling a WIFI function or disabling a Bluetooth function.

It is easy to understand that the specific operation corresponding to each preset bending shape above is not constant, and a user may set the specific operation corresponding to each preset bending shape according to personal preferences.

Preferably, the flexible device may further include a strain sensor, which being connected with the controller 300 and provided on the flexible panel 100, is used for detecting whether the flexible panel 100 undergoes a flexible deformation, and sending a start signal to the controller 300 when the flexible panel 100 is detected to have undergone a flexible deformation; and the controller 300 may send the start signal to the sensors after receiving the start signal so as to start the sensors. That is to say, the strain sensor is provided so that the sensor can be started only when the flexible panel 100 undergoes a flexible deformation, therefore, the service life of the sensor may be prolonged. Particularly in the event that the sensors are photosensitive sensors, the strain sensor can be provided to prevent the emitting components of the photosensitive sensors from always staying in a luminous state, thereby ensuring the normal use of the flexible device.

The strain sensor may include a strain sheet and a signal generation element, wherein the strain sheet is attached to the back surface 102 of the flexible panel 100 to detect whether the flexible panel 100 undergoes a deformation; and when the strain sheet detects that the flexible panel undergoes a deformation, the signal generation element generates a start signal and sends the same to the controller 300.

It should be understood that the embodiments above are only exemplary embodiments utilized to explain the principle of the present invention, however, the present invention is not limited thereto. For those of ordinary skills in the art, various variations and improvements may be made without departing from the spirit and essence of the present invention, and these variations and improvements shall also fall within the protection scope of the present invention.

1. A flexible device, comprising:
a flexible panel, which can be deformed by an external action;
a sensing module, which is used for sensing the deformation of the flexible panel and sending an induced signal;
a controller, which is used for receiving the induced signal and emitting a control signal;
a drive module, which is used for receiving the control signal and generating a corresponding driving signal; and
an execution module, which is used for executing a corresponding action according to the driving signal.

2. The flexible device according to claim 1, wherein the sensing module comprises sensors, the sensors comprise receiving components and emitting components, the emitting components being used for emitting sensing signals, and the receiving components being used for receiving the sensing signals and emitting corresponding induced signals.

3. The flexible device according to claim 2, wherein the receiving components and the emitting components are respectively disposed at different positions on the flexible panel.

4. The flexible device according to claim 3, wherein the total number of the receiving components and the emitting components within each of the sensors is four, and the receiving components and the emitting components are respectively disposed at four corner positions on a same side of the flexible panel.

5. The flexible device according to claim 2, wherein each of the sensors is provided on a front surface or a back surface of the flexible panel.

6. The flexible device according to claim 2, wherein the sensors comprise photosensitive sensors, each of the photosensitive sensors comprises a light emitting component and a plurality of light receiving components, and light signals emitted by the light emitting component are received by different light receiving components according to different deformations of the flexible panel, so that different induced signals are emitted.

7. The flexible device according to claim 2, wherein the sensors comprise touch switches, each of the touch switches comprises an active touch element and a plurality of touch sensing elements, and touches of the active touch element are received by different touch sensing elements according to different deformations of the flexible panel, so that different induced signals are emitted.

8. The flexible device according to claim 7, wherein the sensors emit different induced signals according to different numbers of the contacts between the touch sensing elements and the active touch element within a preset time period.

9. The flexible device according to claim 2, further comprising:
a strain sensor, wherein the strain sensor is used for detecting whether the flexible panel undergoes a flexible deformation, and for sending a start signal to the controller when the flexible panel undergoes a flexible deformation so that the controller activates the sensors.

10. The flexible device according to claim 9, wherein the strain sensor comprises a strain sheet and a signal generation element, the strain sheet is attached to a back surface of the flexible panel to detect whether the flexible panel undergoes a deformation, and when the strain sheet detects that the flexible panel undergoes a deformation, the signal generation element generates the start signal and sends the same to the controller.

11. The flexible device according to claim 1, wherein the drive module comprises one or more of an audio drive module, a wireless network drive module, a camera drive module, a communication drive module, a power source drive module and a display drive module.

12. The flexible device according to claim 1, wherein the execution module comprises one or more of an audio component, a wireless network component, a camera component, a communication component, a power source component and a display component.

13. The flexible device according to claim 3, wherein the sensors comprise photosensitive sensors, each of the photosensitive sensors comprises a light emitting component and a plurality of light receiving components, and light signals emitted by the light emitting component are received by different light receiving components according to different deformations of the flexible panel, so that different induced signals are emitted.

14. The flexible device according to claim 5, wherein the sensors comprise photosensitive sensors, each of the photosensitive sensors comprises a light emitting component and a plurality of light receiving components, and light signals emitted by the light emitting component are received by different light receiving components according to different deformations of the flexible panel, so that different induced signals are emitted.

15. The flexible device according to claim 3, wherein the sensors comprise touch switches, each of the touch switches comprises an active touch element and a plurality of touch sensing elements, and touches of the active touch element are received by different touch sensing elements according to different deformations of the flexible panel, so that different induced signals are emitted.

16. The flexible device according to claim 5, wherein the sensors comprise touch switches, each of the touch switches comprises an active touch element and a plurality of touch sensing elements, and touches of the active touch element are received by different touch sensing elements according to different deformations of the flexible panel, so that different induced signals are emitted.

17. The flexible device according to claim 3, further comprising:
a strain sensor, wherein the strain sensor is used for detecting whether the flexible panel undergoes a flexible deformation, and for sending a start signal to the controller when the flexible panel undergoes a flexible deformation so that the controller activates the sensors.

18. The flexible device according to claim 4, further comprising:
a strain sensor, wherein the strain sensor is used for detecting whether the flexible panel undergoes a flexible deformation, and for sending a start signal to the controller when the flexible panel undergoes a flexible deformation so that the controller activates the sensors.

19. The flexible device according to claim 5, further comprising:
a strain sensor, wherein the strain sensor is used for detecting whether the flexible panel undergoes a flexible deformation, and for sending a start signal to the controller when the flexible panel undergoes a flexible deformation so that the controller activates the sensors.
